(19) United States
(12) Patent Application Publication
(10) Pub. No.: US 2025/0167069 A1
(43) Pub. Date: May 22, 2025

(54) SYSTEM AND METHODS FOR A RADIATIVE NANOMATERIAL PACKAGE ARCHITECTURE

(71) Applicant: Samsung Electronics Co., Ltd., Suwon-si (KR)

(72) Inventors: Radwanul Hasan SIDDIQUE, Monrovia, CA (US); Yibing Michelle WANG, Pasadena, CA (US); Shailabh KUMAR, Pasadena, CA (US); Haeri Park HANANIA, Sierra Madre, CA (US)

(21) Appl. No.: 18/893,956

(22) Filed: Sep. 23, 2024

Related U.S. Application Data
(60) Provisional application No. 63/602,366, filed on Nov. 22, 2023.

(51) Int. Cl. H01L 23/367; H01L 21/48; H01L 23/00; H01L 23/373

(52) U.S. Cl. CPC H01L 23/3675; H01L 21/481; H01L 23/3731; H01L 23/3733; H01L 24/29; H01L 24/32; H01L 2224/29324; H01L 2224/29339; H01L 2224/29347; H01L 2224/29355; H01L 2224/29369; H01L 2224/32225

(57) ABSTRACT

A method, device and system are disclosed including a substrate, a computational device mounted on the substrate, and a heat dissipator thermally coupled to the device. In some embodiments, at least one surface of the computational device has a nanostructure ceramic layer formed upon. In some embodiments, the nanostructure ceramic layer includes at least one of Al₂O₃, Si₃N₄, and BeO. In some embodiments, the at least one surface is on the substrate. In some embodiments, the at least one surface is on the heat dissipator. In some embodiments, the nanostructure ceramic layer includes at least one nanostructure with a diameter in the range of 10-5,000 nm. In some embodiments, the nanostructure ceramic layer may be a repeating pattern of nanostructured elements having uniform sizes and shapes. In some embodiments, the nanostructure ceramic layer is a random pattern of nanostructured elements having non-uniform sizes and shapes

### CROSS-REFERENCE TO RELATED APPLICATION

This application claims the priority benefit under 35 U.S.C. § 119 (e) of U.S. Provisional Application No. 63/602,366 filed on Nov. 22, 2023, the disclosure of which is incorporated herein by reference in its entirety.

### TECHNICAL FIELD

The subject matter disclosed herein relates to microelectronics packaging and integrated circuits (IC) packaging. More particularly, the subject matter disclosed herein relates to a package architecture involving the nanomaterials and nanostructures.

### BACKGROUND

Semiconductor devices may connect to additional devices and circuitry on different substrates. Forming connections between substrates can provide increased computation. However, forming connections between substrates can cause difficulties. Packaging describes the general method for connecting and integrating multiple computational components together in an integrated unit, and may involve multiple different types of integrated circuits on multiple substrates which may combine into a single unit. Packaging may also describe a method for which multiple computational components within a single unit are protected by the use of various techniques to provide thermal, physical and electrical protection It is further noted that background concepts discussed herein are for informational purposes only and are not intended to limit the present disclosure. Nor should the background or field described herein be intended to limit the disclosure herein to a particular use or concept.

### SUMMARY

An example embodiment provides a device, the device including a substrate, a computational device mounted on the substrate, and a heat dissipator thermally coupled to the device. In some embodiments, at least one surface of the computational device has a nanostructure ceramic layer formed upon. In some embodiments, the nanostructure ceramic layer includes at least one of Al₂O₃, Si₃N₄, and BeO. In some embodiments, the at least one surface is on the substrate. In some embodiments, the at least one surface is on the heat dissipator. In some embodiments, the nanostructure ceramic layer includes at least one nanostructure with a diameter in the range of 10-5,000 nm. In some embodiments, the nanostructure ceramic layer may be a repeating pattern of nanostructured elements having uniform sizes and shapes. In some embodiments, the nanostructure ceramic layer is a random pattern of nanostructured elements having non-uniform sizes and shapes.

An example embodiment provides a system, the system including a base substrate, a computation a device mounted on the base substrate, a heat dissipator thermally coupled to the computational device, and a first thermal interface material between the heat dissipator and the computational device. In some embodiments, the first thermal interface material includes a metallic nanoparticle. In some embodiments, the metallic nanoparticle is one or more of Al, Ag, Pt, Ni, or Cu. In some embodiments, the metallic nanoparticle has a diameter between 1 and 500 nm. In some embodiments, the first thermal interface material includes a metallic nanoparticle embedded in a gel matrix. In some embodiments, the first thermal interface material has a Young's Modulus of less than 10 MPa, and a thermal conductivity of greater than 10 W/M° K. In some embodiments, a second thermal interface material is between the computational device and the base substrate, and the second thermal interface material may include a metallic nanoparticle embedded in a gel matrix. In some embodiments, a nanostructured ceramic layer may form a surface of the base substrate or the heat dissipator, the nanostructure ceramic layer may include at least one of Al₂O₃, Si₃N₄, and BeO. In some embodiments, the base substrate may be mounted on a board with a third thermal interface material between the substrate and the board, the third thermal interface material may include a metallic nanoparticle embedded in a gel matrix.

An example embodiment provides a method, the method including mounting a first computational device on a base substrate, mounting a first heat dissipator on the first computational device, depositing a ceramic thin film on at least one of the base substrate, the first computational device, and the first heat dissipator, and forming a nanostructured ceramic layer in the ceramic thin film. In some embodiments, the nanostructure ceramic layer may include at least one of Al₂O₃, Si₃N₄, and BeO. In some embodiments, the nanostructure ceramic layer includes at least one nanostructure with a diameter in the range of 10-5,000 nm. In some embodiments, mounting the first computational device on the base substrate includes inserting a first nano-thermal interface material between the first computational device and the base substrate, and the first nano-thermal interface material may include a metallic nanoparticle embedded in a gel matrix. In some embodiments, mounting the first heat dissipator on the first computational device further includes inserting a second nano-thermal interface material between the first computational device and the first heat dissipator, and the second nano-thermal interface material may include a metallic nanoparticle embedded in a gel matrix. In some embodiments, forming the nanostructured ceramic layer in the ceramic thin film includes patterning the ceramic thin film to reform a repeating pattern of nanostructured elements, the nanostructured elements having a size in the range of 100-5,000 nm.

### BRIEF DESCRIPTION OF THE DRAWING

In the following section, the aspects of the subject matter disclosed herein will be described with reference to exemplary embodiments illustrated in the figures, in which:

FIG. 1 depicts a cross-section view of an example embodiment of a packaging structure according to various embodiments of the subject matter disclosed herein;

FIG. 2 depicts a cross-section view of an example embodiment of a packaging structure according to various embodiments of the subject matter disclosed herein;

FIG. 3A depicts a cross-section view of an example embodiment of a surface structure according to various embodiments of the subject matter disclosed herein;

FIG. 3B depicts a cross-section view of an example embodiment of a surface structure according to various embodiments of the subject matter disclosed herein;

FIG. 3C depicts a cross-section view of an example embodiment of a surface structure according to various embodiments of the subject matter disclosed herein;

FIG. 3D depicts a cross-section view of an example embodiment of a surface structure according to various embodiments of the subject matter disclosed herein;

FIG. 3E depicts a plan view of an example embodiment of a surface structure according to various embodiments of the subject matter disclosed herein;

FIG. 3F depicts a plan view of an example embodiment of a surface structure according to various embodiments of the subject matter disclosed herein;

FIG. 4 depicts a cross-section view of an example embodiment of a packaging structure assembly according to various embodiments of the subject matter disclosed herein;

FIG. 5 depicts a cross-section view of an example embodiment of a packaging structure assembly according to various embodiments of the subject matter disclosed herein

FIG. 6A depicts a cross-section view of an example embodiment of a packaging structure assembly according to various embodiments of the subject matter disclosed herein; and

FIG. 6B depicts a cross-section view of an example embodiment of a packaging structure assembly according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Counter Clockwise,” “Three-Dimensional,” etc.) may be interchangeably used with a corresponding non-capitalized version (e.g., “counter clockwise,” “three-dimensional,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination. Bonding substrates may be thus known in some embodiments as die-to-die (D2D) bonding, wafer-to-wafer bonding (W2 W) or die-to-wafer bonding (D2 W). In some embodiments, the substrates may contain circuits such as integrated circuits including central processing units (CPUs), logic chips, memory such as static random-access memory (SRAM), dynamic random-access memory (DRAM), synchronous dynamic random-access memory (SDRAM), double data rate DRAM or DDR DRAM, application processors (AP), graphical processing units (GPUs), other forms of auxiliary processing units (xPU), artificial intelligence (AI) chips, high bandwidth memory (HBM) interfaces, and other application-specific integrated circuits (ASIC). In some embodiments, a combination of circuits may be present on a substrate. In some embodiments, a substrate may include a packaged chip.

As used herein, high bandwidth memory or HBM, may refer to a chip structure including one or more HBM modules. In some embodiments, the HBM may be manufactured by an advanced silicon node process.

As used herein packaging refers to a process of forming interconnections between substrates. In some embodiments, the interconnections may be between direct surfaces and involve W2 W, D2D, and D2 W bonding. In other embodiments, techniques including wire bonding and other forms of indirect bonding may be performed alone or in combination with W2 W, D2D, and D2 W bonding. In some embodiments, circuits may be bonded directly facing each other, while in other embodiments a flip-chip bonding may be used. In some embodiments, interconnections may be made between substrates on a front or circuit side of the substrate. In other embodiments, interconnections may be made on a rear or back side of the substrate opposite from the circuit structure. In some embodiments, an interconnection may include through-silicon vias (TSVs) or other forms of through-chip vias where one or more substrates may be connected using a via traveling through an interposer such as another substrate or chip. In some embodiments, an interconnection may be formed using connections on a surface of a substrate, such as a pad, and may use additional materials between the pads such as solder to form an interconnection.

As used herein, conductors may refer to a variety of conductive materials, including which materials may be used alone or in combination with other materials such as in the form of an alloy. In some embodiments the conductor is copper (Cu). In some embodiments, copper (Cu) may be in the form of Cu (II), Cu (III) or other forms of copper, alone or in combination with additional elements, including cobalt (Co) and ruthenium (Ru). Such a listing of elements is not intended to be exhaustive, and in other embodiments, any known other type of conductive material may be used.

As used herein, a system-on-a-chip or SOC refers to an integrated circuit that integrates most or all components of a computer into a single die. In some embodiments, the components may include on-chip CPU, memory interfaces, input/output (I/O) devices and interfaces, secondary storage interfaces, and may include other components such GPUs. In some embodiments a SOC may contain digital, analog, mixed-signal, and radio frequency signal processing functions. In some embodiments, the SOC may be manufactured by processes including an advanced silicon node process.

As used herein, nanomaterials refers to materials having an external dimension or internal structure in the nanoscale region. The nanoscale region may be defined as the region below 1 micron, also known as the submicron region. Nanomaterials may include materials having structural elements are in the range between 0.1 nm and 5,000 nm. As used herein, nanostructures refers to structures whose individual structural elements have a size in the nanoscale region, i.e., within the range between 0.1 nm and 5,000 nm. Nanoparticles may include materials in particle form having a size in the range between 0.1 nm and 5,000 nm.

As used herein, size may be used to refer to an approximate diameter, width, thickness, diagonal, or other dimension which has the longest distance within a planar view. As used herein, diameter, when referring to nanoholes may refer alternatively to the length of a diagonal direction within the surface plane the nanoholes are formed in. For example, in some embodiments, the diameter of a nanohole may refer to the diameter of a circular nanohole, the length of the major or semi-major axis of an elliptical nanohole, the diagonal width of a rectangular nanohole, and other similar measures.

As used herein, ceramics refers to inorganic, non-metallic materials. In some embodiments, ceramic materials may include metallic oxides, including aluminum oxide, Al₂O₃, beryllium oxide, BeO, nitrides such as silicon nitride, Si₃N₄, aluminum nitride, AlN, and carbides such as silicon carbide, SiC, and any combination thereof.

Disclosed herein are various embodiments of devices, systems and methods related to packaging architecture and the use of radiative nanostructures and nanomaterials. In some embodiments, nanostructures may be formed using ceramic nanomaterials on a surface of a semiconductor package structure. A semiconductor package structure may include one or more devices mounted on a substrate, with heat conductive structures such as a heat sink having a thermal connection with the one or more devices. In some embodiments, ceramic nanomaterials may be deposited on one or more surface areas of the semiconductor package structure. In some embodiments, the ceramic nanomaterials may be further patterned to form a ceramic nanostructure, having individual elements between 0.1 nm and 1,000 nm in size. A ceramic nanostructure may provide an increase in the radiative heat transferred from the surface areas of the semiconductor package structure. In some embodiments, nanomaterials may be incorporated in a thermal interface material. In some embodiments, a thermal interface material may be placed between elements such as dies, chips and heat sink to enhance thermal conduction. In some embodiments, a thermal interface material may be a soft, gel like material such as a resin or elastomer, or an adhesive, In some embodiments, the thermal interface material may be form from an organic material. In some embodiments, the nanomaterials incorporated in a thermal interface material may be nanoparticles of metallic materials such as copper, aluminum, and silver. In some embodiments, a thermal interface material may be soft and pliable with a Young's Modulus greater than 10 MPa, and may also be highly thermal conductive, having a thermal conductivity greater than 10 W/m° K.

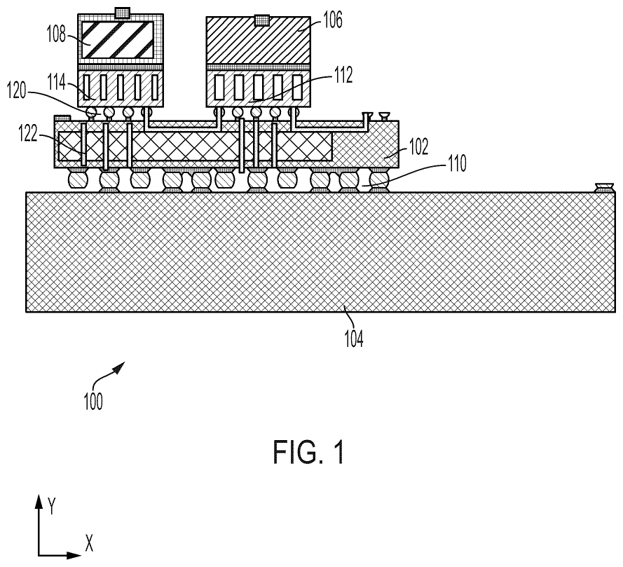

FIG. 1 depicts a perspective view of an exemplary embodiment of a first package architecture 100 which may incorporate the nanomaterials disclosed herein. A base substrate 102 supports at least a first device 106 and a second device 108 (also referred to herein generically as a “device” or “computational device” and collectively as “devices” or “computational devices”). In some embodiments, the devices may include a processor die, or a processor chiplet. In some embodiments, the devices may be various forms of memory including DRAM, SRAM, and other forms of memory. In some embodiments, the devices may include a core device, for example a processor or other form of microcontroller to act as a controller. In some embodiments, the first device 106 and a second device 108 may each comprise a stack of one or more component devices. In some embodiments, additional devices may be mounted on the base substrate 102 in addition to the first device 106 and the second device 108. In some embodiments, only a single device may be mounted on the base substrate 102. In some embodiments, a photonic integrated circuit, PIC, may be mounted on the base substrate 102, with the PIC coupled to transmit a signal to the first device 106 and/or the second device 108.

In some embodiments, the base substrate 102 may be a silicon die, while in other embodiments a variety of semiconductor materials may be used, either alone or in combination. For example, in some embodiments, the base substrate 102 may comprise a SOI substrate such as glass, as well as a germanium, sapphire or other form of semiconductor, either alone, in combination with another semiconductor, or with an insulator such as glass.

The base substrate 102 may be mounted on a supporting substrate 104. In some embodiments, the supporting substrate 104 may take the form of a die, a wafer, an organic substrate, a printed circuit board, a card, or any other known suitable substrate. A substrate interface structure 110 may form a connection between the supporting substrate 104 and the base substrate 102. In some embodiments, a connection may be formed between the substrate interface structure 110 and wiring layers 122, which may transmit electrical signals including power and communications signals between the wiring layers 122 and the supporting substrate 104.

The substrate interface structure 110 may include a conductive connection, such as a bumps, microbumps, pillars, balls, and other forms such as controlled-collapse chip connection (C4) bumps, alone or in combination. As used herein, a C4 bump refers to a form of solder bumps placed on pads on a top surface of a substrate prior to flipping the substrate to form a flip-chip. The substrate interface structure 110 may further include a dielectric material, which may include a material such as an adhesive, resin, or elastomer which may form a connection between the base substrate 102 and the supporting substrate 104 in addition to a conductive connection. In some embodiments, the dielectric material may take the form of an underfill material. In some embodiments, the combination of a conductive connection and a dielectric connection may form a hybrid bond.

Although referred to as wiring layers 122, one or more of the wiring layers 122 may take the form of series of pads, bumps, vias, through-vias, traces, redistribution layers and other forms of conductive connections for redistributing signals in various combinations. Similarly, the redistribution layers may also take the form of series of pads, bumps, vias, through-vias, traces, redistribution layers and other forms of connection for redistributing signals in various combinations.

The conductive connection of the substrate interface structure 110 may transmit power and communication signals between the supporting substrate 104 and the base substrate 102. The electrical signals in the substrate interface structure 110 may then produce heat as a result of resistance within the conductive connection. Heat may also be produced within the wiring layers 122 from the resistance within the wiring layers 122 to the electrical signals being transmitted. In some embodiments, where the wiring layer 122 includes a TSV or other conductive connections embedded in the base substrate 102, heat may be produced within the base substrate 102.

In some embodiments, the wiring layers 122 may further connect to the base substrate 102 to the first device 106 and the second device 108 via a device interface structure 120. The wiring layers 122 may be part of an exchange of electrical power and communication signals between the supporting substrate 104, the base substrate 102, and the first device 106 and the second device 108. In some embodiments, the base substrate 102 may include logic circuits allowing routing between the first device 106, the second device 108, as well as any other devices mounted in connection with the base substrate 102 and the supporting substrate 104. In some embodiments, a PIC may be connected to the wiring layers 122 to couple power and data signals between the first device 106 or the second device 108 and the PIC.

The device interface structure 120 may include a conductive connection, such as a bumps, microbumps, pillars, balls, and other forms such as C4 bumps, alone or in combination. The device interface structure 120 may further include a dielectric material, which may include a material such as an adhesive, resin, or elastomer which may form a connection between the base substrate 102, the first device 106 and second device 108 in addition to a conductive connection. In some embodiments, the dielectric material may take the form of an underfill material. In some embodiments, the combination of a conductive connection and a dielectric connection may form a hybrid bond.

In some embodiments, the first device 106 may have a first heat dissipator 112. In some embodiments, the second device 108 may have a second heat dissipator 114. In some embodiments, such as in the exemplary embodiment of FIG. 1, a heat dissipator may be positioned between a device and the base substrate 102, where the first heat dissipator 112 is between the first device 106 and the base substrate 102, and the second heat dissipator 114 is between the second device 108 and the base substrate 102. In some embodiments, in addition or in alternative to positioning a heat dissipator between a device and the base substrate 102, a heat dissipator may be mounted the sides or top of the device. In the exemplary embodiment of FIG. 1, placing the first heat dissipator 112 between the base substrate 102 and the first device 106 provides a thermal pathway for heat from the base substrate 102, the first device 106, and the device interface structure 120 to transfer out of the first package architecture 100. In some embodiments, a heat dissipator may be made of a thermally conductive material, such as a metal like copper or aluminum, as well as any other known suitable material. A high thermal conductivity may allow heat to transfer via conduction from surrounding materials into the heat dissipator. In some embodiments, a heat dissipator integrated in a heat sink may then transfer the heat from the heat sink into the surrounding environment. For example, in some embodiments, a heat sink may conduct heat into a fluid, such as air or water, where the heat may be transferred away from the heat sink using convective heat transfer. In some embodiments, the fluid may flow passively, while in other embodiments, an active device such as a pump or fan, or any other known form of fluid transfer device, may cause the fluid to move. In addition, or alternatively, a heat dissipator integrated in heat sink may transfer heat radiatively, where the surface of the heat dissipator transfers heat using electromagnetic radiation, as excess thermal energy causes photonic emission from a hot surface. In radiative heat transfer, the heat may be either reabsorbed by surrounding environmental conditions, or may be transmitted into space. As such, in some embodiments, conductive, convective, and radiative heat transfer may each transfer heat from a heat sink.

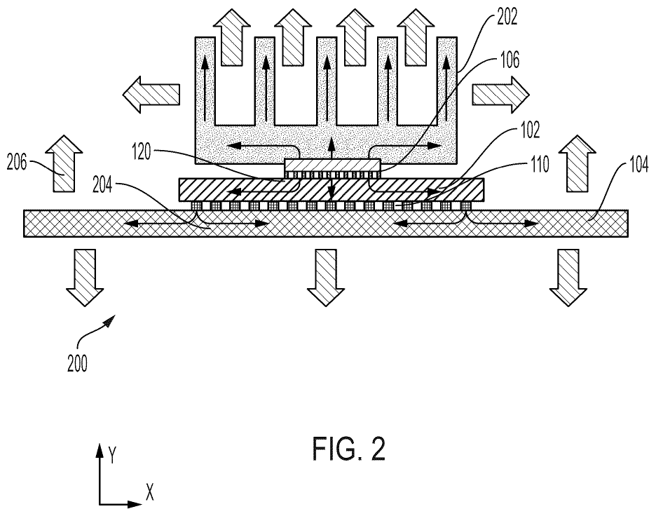

FIG. 2 provides an example of a second package architecture 200, where a single device, the first device 106, is mounted on the base substrate 102. FIG. 2 differs from FIG. 1, as the exemplary embodiment shown in FIG. 2 provides a top-mounted heat dissipator 202 on top of the first device 106 FIG. 2 provides a plurality of thermal paths showing a set of thermal conduction paths for the second package architecture 200, which may be referred to as a thermal exchange. The plurality of thermal paths are just an example, and the actual thermal pathways may vary, as although the first device 106 may be a major heat source, heat may be generated by any electrical conductor in the second package architecture 200, including on the base substrate 102, or the supporting substrate 104. The plurality of thermal paths include a plurality of internal heat paths 204, shown as arrows within the second package architecture 200, and a plurality of external heat paths 206, shown as arrows extending away from the second package architecture 200. Although not shown in FIG. 1, the thermal exchange described with the second package architecture 200 may be applied to the first package architecture 100, or any other package architecture disclosed herein.

The plurality of internal heat paths 204 demonstrate the heat transfer of the exemplary embodiment of FIG. 2 using conduction within the second package architecture 200, with heat generated by the operation of first device 106 transferring to the top-mounted heat dissipator 202, as well as via the device interface structure 120 to the base substrate 102, and via the substrate interface structure 110 to the supporting substrate 104. In other embodiments, the heat transfer paths may vary, and may include additional elements as well as fewer elements.

The plurality of external heat paths 206 demonstrate an example embodiment of how heat may transfer using convection and radiation from the second package architecture 200. As heat transfers conductively from the first device 106 across the second package architecture 200 via the plurality of internal heat paths 204, radiative and convective heat transfer may occur on any exposed surface. The radiative heat transfer may occur on every surface of the second package architecture 200, as radiation will emit from any surface higher than ambient temperature, as the plurality of internal heat paths 204 cause the second package architecture 200 to heat up. In some embodiments, radiative heat transfer may be especially effective from heat dissipator such as the top-mounted heat dissipator 202, however, effective radiative heat transfer may come from any surface having good emissivity. Convective heat transfer may also occur on any exposed surface of the second package architecture 200, heat transferred to a convective fluid using conduction. Convective heat transfer may depend on the convective fluid (i.e. air, liquid), the speed at which such a fluid flows, as well as the volume of the fluid flow. Radiative heat transfer, however, depends largely on the temperature difference of the surface to the ambient environment, and the emissivity (ε) of the surface. Radiative heat transfer from the temperature difference between a surface and the ambient environment is described by the blackbody radiation equation, while emissivity describes the relative efficiency of the surface to an ideal blackbody, generally between 0 and 1 (0<ε<1), with an emissivity of 1 (ε=1) matching the ideal blackbody. In some embodiments, the materials used within a package may have a low emissivity of less than 0.1 (ε<0.1). As such, an increase in radiative heat transfer may be obtained by increasing the emissivity of a surface.

In both the plurality of internal heat paths 204 and the plurality of external heat paths 206, the thermal conductivity of the second package architecture 200 plays a significant role. The plurality of internal heat paths 204 transfer heat away from a heat generation source, such as the first device 106, to other elements able to transfer the heat way from the second package architecture 200 based on the effective thermal conduction between the various components of the second package architecture 200. The plurality of external heat paths 206, transfers the heat internally transferred within the second package architecture 200 to the external environment, with the emissivity of the second package architecture 200 determining how effective the radiative heat transfer is from the second package architecture 200. As such, nanomaterials may be incorporated into the second package architecture 200 in order to effectively increase both the thermal conduction within the second package architecture 200 and the thermal emissivity from the second package architecture 200, which in turn may increase the thermal dissipation from the second package architecture 200. In some embodiments, when the plurality of internal heat paths 204 are formed from a material of high emissivity, the plurality of internal heat paths 204 may also act as part of the plurality of external heat paths 206, with the conducted heat being emitted while being transferred along the plurality of internal heat paths 204.

In some embodiments, a nanomaterial may take the form of an external coating on the second package architecture 200. A ceramic material known for use in packaging applications, such as Al₂O₃, BeO, Si₃N₄, as well as any other suitable ceramic, may be used in the formation of portions of the second package architecture 200, such as part of all of the base substrate 102 or the supporting substrate 104. Such materials have good thermal conductivity and thermal emissivity as well as suitable material properties to enable a wide temperature operating range. In some embodiments, a surface of the second package architecture 200 may be coated with a layer of a ceramic material. In some embodiments, the nanomaterial may take the form of a combination of one or more ceramic materials, and may be formed in one or more layers.

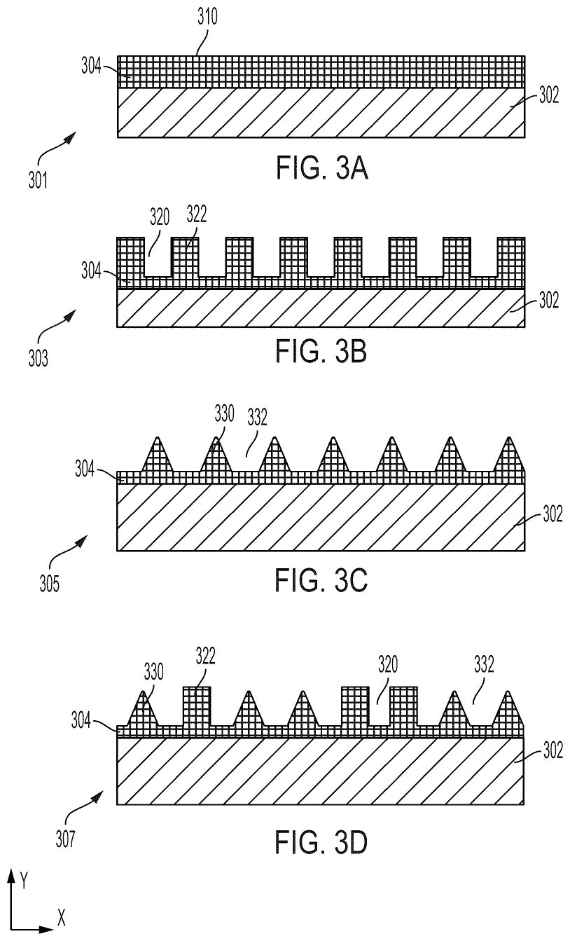

FIG. 3A provides an exemplary embodiment of a layer of ceramic material forming a ceramic layer 304 on a surface of a component 302 of a package architecture, such as the base substrate 102, or any other component of the first package architecture 100 or the second package architecture 200. The ceramic layer 304, as shown in FIG. 3A, is shaped into a flat structure 310, where the ceramic layer 304 is effectively planar. In some embodiments, the ceramic layer 304 may be a thin film layer having a thickness of 10-15 microns, although the thickness may vary higher or lower, and may be as small as 10 nm or less, or as large as 20 microns or more. The ceramic layer 304 may be formed by any appropriate method, such as chemical vapor deposition (CVD), physical vapor deposition (PVD), thermal annealing atomic-layer deposition (ALD), thermal diffusion processes, dipping, electrocoating, and any combination thereof. In some embodiments, as in the exemplary embodiment of FIG. 3A, the flat structure 310 may be effectively planar, such as having had a planarization process, such as chemical mechanical polishing (CMP), or any other known suitable planarization process. In other embodiments, the flat structure 310 may have some roughness or irregularities variations caused by the formation process, such as by non-uniformity in a deposition process. However, in some embodiments the flat structure 310 may processed to create a nanostructure in the ceramic layer 304.

FIG. 3B demonstrates an example of a first nanostructure 303, where the flat structure 310 may be processed so that the ceramic layer 304 includes a first nanostructure 303 on the surface including one or more nanovoids 320 and one or more nanoelements 322. The process may be any suitable process to pattern a surface, including lithography, grinding, polishing, pressing, etching into the surface, as well as deposition techniques such as ALD, PVD, CVD, and molding to build up on a surface, either alone or in combination.

In some embodiments, the one or more nanoelements 322 may have a diameter in the range of 10-5,000 nm, although in some embodiments, the diameter may be smaller or larger. In some embodiments, such as the exemplary embodiment of FIG. 3B, the one or more nanoelements 322 may be shaped as a rectangular prism, while in others the one or more nanoelements 322 may be shaped in any suitable form, such as pyramids, cylinders, hemispheres, as well as irregular shapes. In some embodiments, the one or more nanoelements 322 may have uniforms shapes and sizes, while in other embodiments, the one or more nanoelements 322 may have a plurality of shapes and sizes.

In some embodiments, the one or more nanovoids 320 may have a diameter in the range of 100-5,000 nm, although in some embodiments, the diameter may be smaller or larger. In some embodiments, such as the exemplary embodiment of FIG. 3B, the one or more nanovoids 320 may be shaped to fit the spaces between the one or more nanoelements 322. In some embodiments, the one or more nanovoids 320 may have uniforms shapes and sizes, while in other embodiments, the one or more nanovoids 320 may have a plurality of shapes and sizes.

In some embodiments, the one or more nanoelements 322 and the one or more nanovoids 320 may form a repeating pattern, while in other embodiments, either of the one or more nanoelements 322 and the one or more nanovoids 320 may be randomly aligned. In some embodiments, the one or more nanovoids 320 and the one or more nanoelements 322 may have regular spacing, while in other embodiments, the spacing between the one or more nanovoids 320 and the one or more nanoelements 322 may vary. In some embodiments, the one or more nanovoids 320 and the one or more nanoelements 322 may have the same orientation, while in other embodiments the orientation of either the one or more nanovoids 320 and the one or more nanoelements 322 may vary.

FIG. 3C provides an exemplary embodiment of a second nanostructure 305 different from the first nanostructure 303. While the first nanostructure 303 may be formed into a series of one or more nanoelements 322 and one or more nanovoids 320, the second nanostructure 305 may have one or more nanopeaks 330 and one or more nanovalleys 332. In the exemplary embodiment of FIG. 3C, the one or more nanopeaks 330 are shown having a triangular cross section, while the one or more nanovalleys 332 are shown as having a flat area between the one or more nanopeaks 330. However, the shape, size, uniformity, spacing, patterning, and orientation of the one or more nanopeaks 330 and the one or more nanovalleys 332 may vary. In some embodiments, the one or more nanopeaks 330 may have a diameter in the range of 10-5,000 nm, although in some embodiments, the diameter may be smaller or larger. In some embodiments, such as the exemplary embodiment of FIG. 3C, the one or more nanopeaks 330 may be shaped as a pyramid, while in others the one or more nanopeaks 330 may be shaped in any suitable form, such as prisms, cylinders, hemispheres, as well as irregular shapes. In some embodiments, the one or more nanopeaks 330 may have uniforms shapes and sizes, while in other embodiments, the one or more nanopeaks 330 may have a plurality of shapes and sizes. In some embodiments, the one or more nanopeaks 330 may have a regular spacing, while in other embodiments, the one or more nanopeaks 330 may have an irregular spacing, while still other embodiments may have the one or more nanopeaks 330 with a random spacing. In some embodiments, the one or more nanopeaks 330 may have the same orientation, while in other embodiments the orientation of the one or more nanopeaks 330 may vary. The one or more nanovalleys 332 may thus have their size vary based on the spacing and layout of the one or more nanopeaks 330.

FIG. 3D provides an exemplary embodiment of a third nanostructure 307 different from the first nanostructure 303 and the second nanostructure 305. The third nanostructure 307 may combine the one or more nanovoids 320, the one or more nanoelements 322, the one or more nanopeaks 330, and the one or more nanovalleys 332. The number, layout, size, spacing, and orientation of the one or more nanovoids 320, the one or more nanoelements 322, the one or more nanopeaks 330, and the one or more nanovalleys 332 may be uniform or may vary as discussed above with the exemplary embodiments of FIG. 3B and FIG. 3C. Furthermore, the layout of the third nanostructure 307 may be regular, irregular, or random.

The formation of a nanostructure on a package surface may increase the surface area on the package surface without an increase in volume. Such an increase in surface area may increase the effective emissivity of the package surface with a nanostructure. In some embodiments, forming a nanostructure on a package surface may increase the emissivity of the package surface by up to 5 times or more compared to an unstructured surface, while in other embodiments the emissivity increase may vary and be higher or lower compared to an unstructured surface. In some embodiments, a previously low emissivity package material of 0.1 may be increased to 0.5 or more (ε>0.5), for example, anodizing an aluminum surface may increase the emissivity from 0.09 to 0.85, although the increase may be larger or smaller. In some embodiments, the relative cooling experienced by a device using such a nanostructure may be greater than 10° C. compared to an unstructured surface, while in other embodiments the cooling compared to an unstructured surface may vary and be higher or lower.

FIG. 3E provides an exemplary embodiment of a fourth nanostructure 309, with FIG. 3E providing a plan view compared to the cross-sectional views of FIGS. A-3D. The exemplary embodiment of FIG. 3E provides a variety of sizes for each of the one or more nanoelements 322, with the one or more nanoelements 322 having a generally ellipsoid shape. In the exemplary embodiment of FIG. 3E, the one or more nanovoids 320 between the one or more nanoelements 322 may be relatively large, having the spacing between the one or more nanoelements 322 be large enough so that the one or more nanovoids 320 make up a large percentage of the exposed surface. In some embodiments, a larger percentage of surface space taken up by the one or more nanovoids 320 may be referred to as a loosely packed surface. In some embodiments, nanoelements such as those of the one or more nanoelements 322 displayed in FIG. 3E, may be formed as droplets via a process such as a deposition process.

FIG. 3F provides an exemplary embodiment of a fifth nanostructure 311, with FIG. 3F providing a plan view of an embodiment differing from the fourth nanostructure 309 of FIG. 3E. The exemplary embodiment of FIG. 3F differs from the exemplary embodiment of FIG. 3E in both the shape of the one or more nanoelements 322 and the spacing between the one or more nanoelements 322. The one or more nanoelements 322 in the exemplary embodiment of FIG. 3F have a more irregular shape than the exemplary embodiment of FIG. 3E, similar to gravel or pebbles, with the individual elements of the one or more nanoelements 322 formed, for example, via a process such as a thermal annealing or diffusion process, where a ceramic material may experience growth and cracking on the nanoscale, forming a rough surface. The one or more nanoelements 322 in the exemplary embodiment of FIG. 3F also may have a smaller spacing than the exemplary embodiment of FIG. 3E, such that the surface space taken up by the one or more nanovoids 320 is considerably less. A dense spacing of the one or more nanoelements 322 may be referred to as a closely packed surface.

In some embodiments, a thermal interface material or TIM, may be used between any of the components of the first package architecture 100 or the second package architecture 200. A thermal interface material provides an increased conductive path between components, allowing heat to transfer more easily via thermal conduction from a component producing heat such as the first device 106 to another component radiating heat such as a heat sink.

In some embodiments, a thermal interface material may incorporate a nanomaterial, and may be known as a nano-thermal interface material, or NTIM. In some embodiments, the nano-thermal interface material may incorporate nanoparticles of ceramic including aluminum oxide, aluminum nitride and beryllium oxide, either alone or in combination along with any other suitable ceramic. In some embodiments, the nano-thermal interface material may incorporate nanoparticles of metals including aluminum, silver, and copper, either alone or in combination along with any other suitable metal. In some embodiments, the nanoparticles of metals may be formed of substantially a single metal, while in other embodiments, an alloy may be used. In some embodiments, the metallic nanoparticles may have a high bulk thermal conductivity, where copper may have a bulk thermal conductivity of 401 W/m° K, where silver may have a bulk thermal conductivity of 310 W/m° K, and where aluminum may have a bulk thermal conductivity of 270 W/m° K. In some embodiments, the nanoparticles incorporated in the nano-thermal interface material may be nanostructured, and may have a diameter in the range of 0.1 to 100 nm, although the diameter may vary depending on the desired configuration. In some embodiments, Al nanoparticles may provide an ultrafast electron-phonon coupling of 0.5 picosecond ps leading to higher heat dissipation rate, while Ag and Cu nanoparticles have an electron-phonon coupling of 3.0 ps. In some embodiments, a low electron-phonon coupling may provide an increase in heat transfer regardless of the bulk thermal conductivity.

The nano-thermal interface material described herein may be placed within a package architecture such as the first package architecture 100 or the second package architecture 200 at the junction of any components. For example, in some embodiments, the nano-thermal interface material may be between a first device 106 and the base substrate 102. In some embodiments, nano-thermal interface material may form part of the device interface structure 120, and may take the form of a dielectric material forming part of the device interface structure 120, and may be injected as underfill, or used within an adhesive. In some embodiments, the nano-thermal interface material may be between the base substrate 102 and the supporting substrate 104. In some embodiments, the nano-thermal interface material may form part of the substrate interface structure 110, and may take the form of a dielectric material forming part of the substrate interface structure 110, and may be injected as underfill, or used within an adhesive. In some embodiments, the nano-thermal interface material may be placed between a device and a corresponding heat dissipator, for example, between the first device 106 and the first heat dissipator 112 in FIG. 1, or between the first device 106 and the top-mounted heat dissipator 202 of FIG. 2. In further embodiments, the nano-thermal interface material may be injected between additional devices and the base substrate 102, as well as between those devices and any corresponding heat dissipator, as well as any interposers or supporting boards or cards. Furthermore, in some embodiments, the nano-thermal interface material may be between additional components such as a liquid heat sink or a package lid.

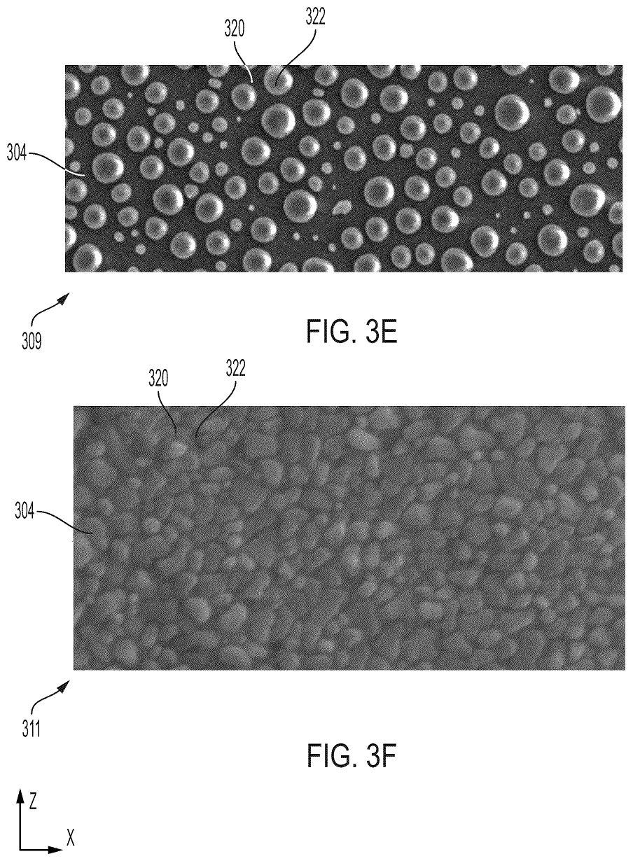

FIG. 4. provides an exemplary embodiment of a third package architecture 400 able to incorporate the nano-thermal interface material as part of a fluidic heat exchanger 406, as opposed to the radiative heat dissipator of FIG. 1 and FIG. 2. In the exemplary embodiment of FIG. 4, the fluidic heat exchanger 406 has an inlet 420 for receiving cold fluid and an outlet 422 for expelling hot fluid. Cold fluid may be actively or passively sent via the fluidic heat exchanger 406 to provide a convective heat transfer from the third package architecture 400 to the fluid. In some embodiments, the fluid may be actively sent, with a mechanism such as a pump or a fan, or any other suitable method of fluid transfer, to force the flow of the fluid, while in other embodiments, the fluid path may be shaped to allow passive flow of the fluid, or use any other mechanism for passive transport, for example, using a fluid experiencing a phase change. In some embodiments, the fluid may travel in a cycle to one or more additional heat exchanges to cool hot fluid and provide fresh cold fluid for the inlet. In some embodiments, the fluid path may be open ended, with hot fluid discarded. In some embodiments, a combination of cyclic and open paths may be used, with fluid being cycled a set number of times before removal.

In some examples, such as the exemplary embodiment of FIG. 4, the fluidic heat exchanger 406 is mounted on top of a package lid 410 for the third package architecture 400. The package lid 410 may provide thermal, mechanical, and electrical protection for the third package architecture 400, and also provide mechanical stability and support for the fluidic heat exchanger 406, as well as a thermal path between the first device 106 and the fluidic heat exchanger 406. Additionally, the package lid 410 may prevent fluid from the fluidic heat exchanger 406 from reaching the first device 106. In the illustrated embodiment, the package lid 410 may be mounted on the base substrate 102, although in other embodiments, the package lid 410 may be mounted on other surfaces, such as the supporting substrate 104.

In some embodiments, such as the exemplary embodiment of FIG. 4, a first nano-thermal interface material 402 may be used at a first interface between the first device 106 and the package lid 410. The first nano-thermal interface material 402 may be inserted in a gap between the first device 106 and the package lid 410, forming a conductive heat pathway between the package lid 410 and the first device 106. In some embodiments, a second nano-thermal interface material 404 may be used at a second interface between the package lid 410 and the fluidic heat exchanger 406. The second nano-thermal interface material 404 may thus form a conductive heat pathway between the fluidic heat exchanger 406 and the package lid 410. The first nano-thermal interface material 402 and the second nano-thermal interface material 404 may thus together form a conductive thermal pathway between the first device 106 and the fluidic heat exchanger 406. In some embodiments, the first nano-thermal interface material 402 and the second nano-thermal interface material 404 may be the same nano-thermal interface material, while in some embodiments, the first nano-thermal interface material and the second nano-thermal interface material may vary.

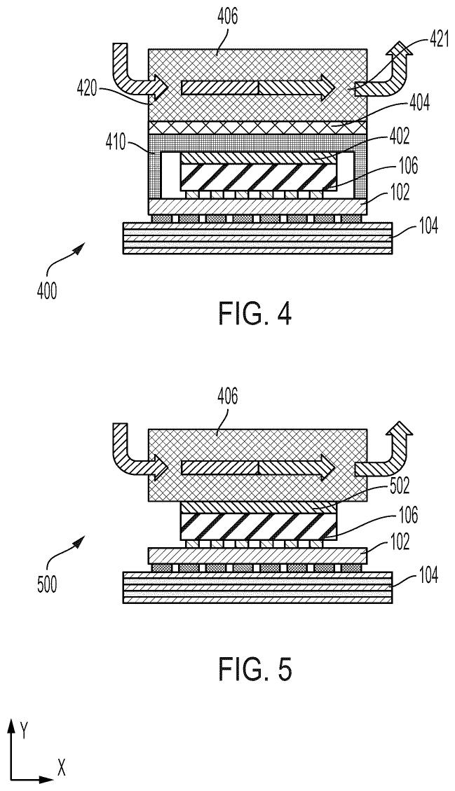

FIG. 5 depicts an example embodiment of fourth package architecture 500, where unlike the third package architecture 400 of FIG. 4, the first device 106 may connect directly to the fluidic heat exchanger 406. In some embodiments, such as the example embodiment of fourth package architecture 500, a third interface may be between the fluidic heat exchanger 406 and the first device 106. In some embodiments, a third nano-thermal interface material 502 may be inserted into the third interface, and form a thermal conductive path between the fluidic heat exchanger 406 and the first device 106.

As shown in some of the exemplary embodiments above, a nano-thermal interface material may be used between various components of the package architectures disclosed herein. As such, the nano-thermal interface materials may be incorporated in various soft and pliable materials suitable for insertion between materials, and may in some embodiments, be embedded within a resin, polymer, adhesive, elastomer, or other suitable material. While the nano-thermal interface material should be highly thermal conductive, the use of the material with electrical components would require the material as a whole to be electrically non-conductive, using a dielectric material. In some embodiments, the nano-thermal interface material may take the form of a gel matrix with nanoparticles dispersed therein. The gel matrix may be a soft and pliable organic and/or inorganic material, and may include, in some embodiments, one or more of agarose, polyacrylamide, hydrogels such as poly(ethylene glycol) (PEG) or poly(vinyl alcohol) (PVA), silica, cellulose, chitosan, polyacrylamide, although the material may vary, and in other embodiments may include any other suitable material, depending on the concentration and cross-linking conditions. In some embodiments, the nano-thermal interface material may have a Young's Modulus below a threshold, which in some embodiments may be less than 10 MPa, although in other embodiments the threshold may vary larger or smaller.

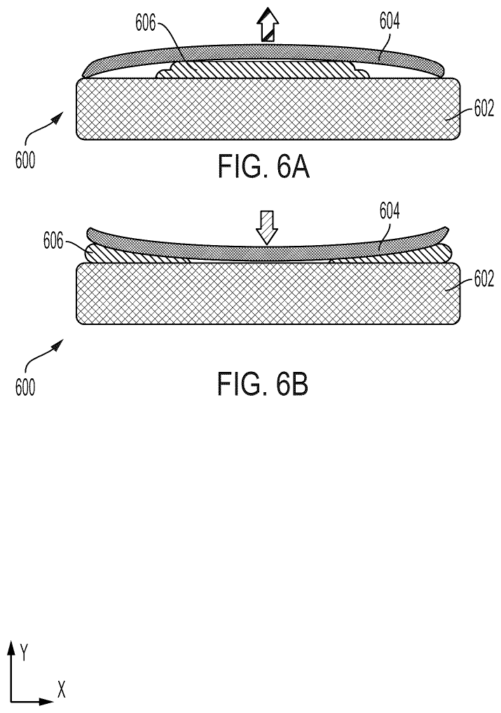

FIG. 6A provides an exemplary embodiment of a first condition for a thermal junction 600, in which the thermal junction 600 is being heated. FIG. 6B provides an exemplary embodiment of a second condition for the thermal junction 600, in which the thermal junction 600 is being cooled. In FIGS. 6A and 6B, a base plate 604 is attached to a heat dissipator 602 using a thermal paste 606 incorporating a nano-thermal interface material. In the first condition, the thermal junction 600 is hot, inducing a thermal expansion in the base plate 604, causing the base plate 604 to swell outwards from the heat dissipator 602. In the second condition, the thermal junction 600 is cold, inducing a thermal contraction in the base plate 604, causing the base plate 604 to buckle inwards from the heat dissipator 602. As such, the thermal paste 606, may experience thermal contraction and thermal expansion over a number of heat cycles. Thus, the thermal paste 606, which incorporates a soft and pliable nano-thermal interface material, will allow for the base plate 604 to thermally cycle without experiencing damage due to repeated expansion and contraction cycles.

In some embodiments, a nano-thermal interface material may incorporate metal nanoparticles, such as aluminum, copper, and silver, along with any other known suitable metals, either alone in combination, within a gel matrix of soft organic material to produce a soft and pliable nano-thermal interface material having a Young's Modulus below a threshold, which in some embodiments may be less than 10 MPa, although in other embodiments the threshold may vary larger or smaller. Furthermore, in some embodiments, the nano-thermal interface material may have a thermal conductivity greater than 10 W/M° K.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a substrate;
a computational device mounted on the substrate; and
a heat dissipator thermally coupled to the device,
wherein at least one surface of the computational device has a nanostructured ceramic layer formed thereon.

2. The device of claim 1, wherein the nanostructured ceramic layer comprises at least one member selected from the group consisting of Al₂O₃, Si₃N₄, and BeO.

3. The device of claim 1, wherein the at least one surface is on the substrate.

4. The device of claim 1, wherein the at least one surface is on the heat dissipator.

5. The device of claim 1, wherein the nanostructured ceramic layer includes at least one nanostructure with a diameter in a range of 10-5,000 nm.

6. The device of claim 1, wherein the nanostructured ceramic layer comprises a repeating pattern of nanostructured elements, the nanostructured elements having a uniform sizes and shapes.

7. The device of claim 1, wherein the nanostructured ceramic layer comprises a random pattern of nanostructured elements, the nanostructured elements having a non-uniform sizes and shapes.

8. A system comprising:
a base substrate;
a computational device mounted on the base substrate;
a heat dissipator thermally coupled to the computational device; and
a first thermal interface material between heat dissipator and the computational device,
wherein the first thermal interface material comprises a metallic nanoparticle.

9. The system of claim 8, wherein the metallic nanoparticle comprises Al, Ag, Pt, Ni or Cu.

10. The system of claim 8, wherein the metallic nanoparticle has a diameter between 1 and 500 nm.

11. The system of claim 8, wherein the first thermal interface material comprises the metallic nanoparticle embedded in a gel matrix.

12. The system of claim 8, wherein the first thermal interface material has a Young's Modulus of less than 10 MPa, and wherein the first thermal interface material has a thermal conductivity of greater than 10 W/M° K.

13. The system of claim 8, further comprising a second thermal interface material between the computational device and the base substrate,
wherein the second thermal interface material comprises a metallic nanoparticle embedded in a gel matrix.

14. The system of claim 8, further comprising a nanostructured ceramic layer, wherein the nanostructured ceramic layer forms a surface of the base substrate or the heat dissipator,
wherein the nanostructured ceramic layer comprises at least one member selected from the group consisting of Al₂O₃, Si₃N₄, and BeO.

15. The system of claim 8, further comprising:
a board, wherein the base substrate mounted on the board; and
a third thermal interface material between the substrate and the board,
wherein the third thermal interface material comprises a metallic nanoparticle embedded in a gel matrix.

16. A method comprising:
mounting a first computational device on a base substrate;
mounting a first heat dissipator on the first computational device;
depositing a ceramic thin film on at least one of the base substrate, the first computational device, and the first heat dissipator; and
forming a nanostructured ceramic layer in the ceramic thin film.

17. The method of claim 16, wherein the nanostructured ceramic layer comprises at least one member selected from the group consisting of Al₂O₃, Si₃N₄, and BeO, and wherein the nanostructured ceramic layer includes at least one nanostructure with a size in a range of 10-5,000 nm.

18. The method of claim 16, wherein mounting the first computational device on the base substrate comprises inserting a first nano-thermal interface material between the first computational device and the base substrate, and
wherein the first nano-thermal interface material comprises a metallic nanoparticle embedded in a gel matrix.

19. The method of claim 18, wherein mounting the first heat dissipator on the first computational device further comprises inserting a second nano-thermal interface material between the first computational device and the first heat dissipator, and
wherein the second nano-thermal interface material comprises a metallic nanoparticle embedded in a gel matrix.

20. The method of claim 16, wherein forming the nanostructured ceramic layer in the ceramic thin film further comprises patterning the ceramic thin film to form a repeating pattern of nanostructured elements, the nanostructured elements having a size in a range of 100-5,000 nm.
